(19) United States
(12) Patent Application Publication
(10) Pub. No.: US 2025/0226841 A1
(43) Pub. Date: Jul. 10, 2025

(54) INTERFACE DATA COMPRESSION FOR HYBRID DATA PROCESSING ARCHITECTURES

(71) Applicant: Intel Corporation, Santa Clara, CA (US)

(72) Inventors: Palanivel Guruva reddiar, Gilbert, AZ (US); Suresh Vasu, Bengaluru (IN); Vivek Sharma, Dehradun (IN); Shishira Shetty Kenjoor Subhashchandra Shetty, Bengaluru (IN)

(73) Assignee: Intel Corporation, Santa Clara, CA (US)

(21) Appl. No.: 19/092,803

(22) Filed: Mar. 27, 2025

(51) Int. Cl. H03M 7/30; G06F 13/42

(52) U.S. Cl. CPC H03M 7/6011; G06F 13/4221; G06F 2213/0026

(57) ABSTRACT

Systems, apparatus, articles of manufacture, and methods to provide interface data compression for hybrid data processing architectures are disclosed. An example apparatus disclosed herein includes communicates with a device to determine interface compression capability information, The disclosed example apparatus also determines, based on the interface compression capability information, whether a host and the device implement one or more interface compression algorithms in common, the one or more interface compression algorithms to provide data compression over a bus interface between a host and the device. The disclosed example apparatus further configures, in response to a determination that the host and the device implement one or more interface compression algorithms in common, a first interface compression algorithm of the one or more interface compression algorithms to operate on the host and on the device to compress data communicated over the bus interface.

### BACKGROUND

Hybrid data processing architectures utilize combinations of integrated processors and discrete processors to implement data processing applications. A compute system employing a hybrid data processing architecture utilizes a combination of at least one integrated processor circuit, such as an integrated graphics processing unit (GPU), included in a host device of the compute system and at least one discrete processor circuit, such as a discrete GPU, included in a secondary device coupled to the host device via an interface to implement an overall data processing application, such as a media analytics application. Media analytics applications involve video processing stages (e.g., such as video decoding, color space conversion, frame scaling and/or cropping, etc.) along with the analytics stages involving application of one more machine learning models (e.g., deep learning models, computer vision model, etc.). As the complexity of machine learning models and video processing algorithms increases, implementation of such models and algorithms involves corresponding increases in system compute, power and/or memory bandwidth consumption. Hybrid data processing architectures split the machine learning models and the video processing algorithms used in media analytics applications among integrated and discrete processor circuits of the system to meet the overall compute, power and/or memory bandwidth requirements.

### BRIEF DESCRIPTION OF THE DRAWINGS

FIG. 1 is a block diagram of a first example compute system that implements interface data compression for hybrid data processing in accordance with teachings of this disclosure.

FIG. 2 is a block diagram of a second example compute system that includes an example host interface compression subsystem and an example device interface compression subsystem to implement interface data compression for hybrid data processing in accordance with teachings of this disclosure.

FIG. 3 illustrates a block diagram of example host compression configuration circuitry included in the host interface compression subsystem of FIG. 2 and a block diagram of example device compression configuration circuitry included in the device interface compression subsystem of FIG. 2.

FIG. 4 is a flowchart representative of example machine-readable instructions and/or example operations that may be executed, instantiated, and/or performed by example programmable circuitry to implement interface compression negotiation in the host compression configuration circuitry of FIGS. 2-3.

FIG. 5 is a flowchart representative of example machine-readable instructions and/or example operations that may be executed, instantiated, and/or performed by example programmable circuitry to implement interface compression adjustment in the host compression configuration circuitry of FIGS. 2-3.

FIG. 6 is a flowchart representative of example machine-readable instructions and/or example operations that may be executed, instantiated, and/or performed by example programmable circuitry to implement interface compression negotiation in the device compression configuration circuitry of FIGS. 2-3.

FIG. 7 is a flowchart representative of example machine-readable instructions and/or example operations that may be executed, instantiated, and/or performed by example programmable circuitry to implement interface compression adjustment in the device compression configuration circuitry of FIGS. 2-3.

FIG. 8 illustrates example performance results achievable by interface data compression for hybrid data processing as disclosed herein.

FIG. 9 is a block diagram of an example processing platform including programmable circuitry structured to execute, instantiate, and/or perform the example machine-readable instructions and/or perform the example operations of FIGS. 4-7 to implement the host interface compression subsystem 165 and the device interface compression subsystem 170 of FIGS. 2-3.

FIG. 10 is a block diagram of an example implementation of the programmable circuitry of FIG. 9.

FIG. 11 is a block diagram of another example implementation of the programmable circuitry of FIG. 9.

FIG. 12 is a block diagram of an example software/firmware/instructions distribution platform (e.g., one or more servers) to distribute software, instructions, and/or firmware (e.g., corresponding to the example machine-readable instructions of FIGS. 4-7) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

As mentioned above, media analytics applications are examples of applications that can benefit from hybrid data processing architectures. A compute system may implement a media analytics application with a hybrid data processing architecture that employs a combination of at least one integrated processor circuit, such as an integrated GPU, included in a host device of the compute system and at least one discrete processor circuit, such as a discrete GPU, included in a secondary device coupled to the host via a bus interface, such as a peripheral component interconnect (PCI) express® (PCIe®) interface as defined in, for example, the PCIe® 6.0 Specification, published 2022. For example, an integrated GPU of the compute system's host device (which may be included on the motherboard of the host device) may implement the video processing components of the media analytics application, whereas a discrete GPU of the compute system's secondary device may implement the machine learning components of the media analytics application. In such an example, the host's integrated GPU may communicate decoded video over the compute system bus interface (e.g., the PCIe interface) to the secondary device's discrete GPU for machine learning processing, and the secondary device's discrete GPU may communicate inference results to the host's integrated GPU also over the compute system bus interface (e.g., the PCIe interface).

Such a hybrid data processing architecture may place a substantial burden on the compute system's bus interface between the host device and the secondary device. For example, communicating decoded video over the bus interface may consume substantial bandwidth and become a bottleneck that limits the amount of video streams (e.g., also referred to as the stream density) that can be processed by the compute system at a given time. Example interface data compression techniques disclosed herein are able to reduce the data traffic over the bus interface(s) of a hybrid data processing compute system relative to other systems that do not employ interface data compression. As such, compute systems that employ example interface data compression techniques as disclosed herein can implement efficient hybrid video processing architectures that distribute video/graphics and machine learning processing among integrated host processors and discrete device processors effectively.

Example systems, apparatus, articles of manufacture, and methods disclosed herein implement interface data compression for hybrid data processing architectures such that data compression is provided at the system bus interface, such as a PCIe interface, between a host device and a secondary device of the system. Relative to systems that do not support interface data compression, such compression reduces the PCIe interface bandwidth utilized to communicate data between the host device and the secondary device(s) to implement hybrid data processing applications, thereby freeing up bandwidth for other applications and/or allowing the hybrid data processing applications to process more workloads.

As used herein, a host device of a compute system refers to the primary compute device, also referred to as the primary processor platform, the primary compute platform, the primary processor device, etc., of the system. In some examples, a host device has sufficient hardware and software capabilities to boot up, provide data input, data output and data processing capabilities, network access capabilities, etc., in a standalone manner and/or coupled to a network. In contrast, as used herein, a secondary device of a compute system refers to a secondary compute device, also referred to as a secondary processor platform, a secondary compute platform, a secondary processor device, etc., that is unable to operate on its own, but is able to operate after being coupled or otherwise connected to the system host.

For example, the host device of a compute system may include the system motherboard, one or more central processing unit (CPUs), GPUs, and/or other circuits integrated on the system motherboard, one or more memories and/or storage devices, one or more input devices, one or more output devices, one or more power supplies, one or more network interfaces, one or more bus interfaces, such as a PCIe interface, etc., to enable the host to operate as a standalone platform and/or coupled to a network. In contrast, a secondary device of the compute system may be a card, device, etc., that couples to the host via the PCIe interface and/or some other bus interface, and provides additional discrete hardware and/or software functionality that is separate from the integrated hardware and/or software functionality of the host, but that is able to be accessed and/or used by the host. For example, a secondary device may be a card that includes one or more discrete GPUs and/or other circuits able to be accessed and/or used by the host to implement one or more applications, such as the video analytics applications mentioned herein.

As disclosed in further detail below, example interface data compression techniques disclosed herein perform an initial compression negotiation procedure that occurs after system boot-up and/or during a platform pairing operation when the host device discovers the secondary device has been coupled to the system. In an example compression negotiation procedure, the host device performs handshaking with the secondary device to discover the interface compression capabilities resident on the secondary device. Based on the discovered capabilities of the secondary device, the host device may then select a given interface compression algorithm that is both resident on the host device and resident on the secondary device, and then configure the selected interface compression algorithm for operation over the PCIe interface between the host device and the secondary device. In some examples, if the host device determines the secondary device does not support an adequate resident interface compression capability, the host device may download compression software to the secondary device that can be configured and executed to provide data compression over the PCIe interface between the host device and the secondary device.

As disclosed in further detail below, some example interface data compression techniques disclosed herein also dynamically adapt the compression used over the PCIe interface during system runtime. In some such examples, the host device may access compression context information associated with the data being communicated between the host device and the secondary device over the PCIe interface. For example, the host device may access compression context information that specifies, indicates, or otherwise describes the content of the data being communicated, one or more application statistics (e.g., such as machine learning model statistics) associated with the data being communicated, an amount of data being communicated, etc. Based on the accessed compression context information, the host device may detect that a compression context change has occurred relative to an initial or expected compression context that was used to establish the interface compression during the negotiation procedure described above. In some such examples, after detection of a compression context change, the host device reconfigures the interface compression algorithm being used over the PCIe interface between the host device and the secondary device. For example, the host device may communicate with the secondary device to adjust one or more parameters of the existing interface compression algorithm (e.g., such as a width of the compression boundary), or may communicate with the secondary device to replace the existing compression algorithm with a different compression algorithm, etc. In this way, example interface data compression techniques disclosed herein can adapt the compression used over the PCIe interface based on current system conditions (e.g., to increase the compression rate to support a higher effective data throughput, to decrease the compression rate to reduce power consumption while meeting performance targets, etc.).

Although the examples described herein focus on interface data compression in the context of providing compression over a PCIe interface, interface data compression as disclosed herein is not limited thereto. On the contrary, interface data compression as disclosed herein can be incorporated in other bus interface(s), such a serial bus interface(s), parallel bus interface(s), etc., and/or other data interfaces, etc., of a compute system to compress data communicated between integrated processor circuit(s) and discrete processor circuit(s) of the system.

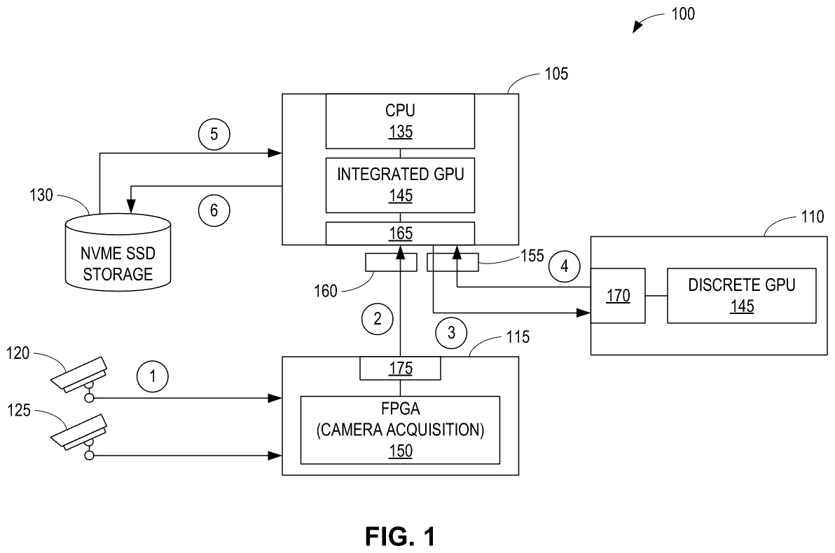

Turning to the figures, FIG. 1 is a block diagram of an example compute system 100 that implements interface data compression for hybrid data processing in accordance with teachings of this disclosure. The compute system 100 of FIG. 1 implements an example hybrid data processing architecture to support an example video analytics application. The compute system 100 includes an example host device 105, example secondary devices 110 and 115, example video cameras 120 and 125, and example storage 130. The host device 105 of the illustrated example includes an example CPU 135 and an example integrated GPU 140. The secondary device 110 of the illustrated example includes an example discrete GPU 145. In the illustrated example, the GPU 140 is referred to as an integrated GPU because it is integrated in the host device 105. In the illustrated example, the GPU 145 is referred to as a discrete GPU because it is separate or, in other words, discrete from the host device 105. The secondary device 110 of the illustrated example includes an example discrete field programmable gate array (FPGA) 150. In the illustrated example, the FPGA 150 is referred to as a discrete FPGA because it is separate or, in other words, discrete from the host device 105.

In the illustrated example, the secondary devices 110 and 115 are coupled to the host device 105 via respective example bus interfaces 155 and 160, which correspond to example PCIe interfaces 155 and 160. To implement interface data compression over the PCIe interface 155 between the host device 105 and the secondary device 110, the host device 105 includes an example host interface compression subsystem 165 and the secondary device 110 includes an example device interface compression subsystem 170. To implement interface data compression over the PCIe interface 160 between the host device 105 and the secondary device 115, the host device 105 includes the example host interface compression subsystem 165 and the secondary device 115 includes an example device interface compression subsystem 175. Operation of the host interface compression subsystem 165 and the device interface compression subsystems 170 and 175 to implement interface data compression is described in further detail below.

The example compute system 100 of FIG. 1 implements an example hybrid video analytics application as follows. At operation 1, the video cameras 120 and 125 capture and stream video signals to the secondary device 115. The video cameras 120 and 125 may include any number and/or type(s) of video cameras and/or other sensors capable of capturing video and/or images in the visible light spectrum, the infrared spectrum, the ultraviolet light spectrum, etc., or any combination thereof. The video cameras 120 and 125 may format the video signals in any appropriate video/image format for receipt by the secondary device 115.

In the illustrated example of FIG. 1, the discrete FPGA 150 included in the secondary device 115 implements a video signal acquisition algorithm to acquire the video signals from the video cameras 120 and 125 and convert the video signals into any appropriate format suitable for subsequent processing. For example, the discrete FPGA 150 may sample the video signals acquired from the video cameras 120 and 125 at a suitable sampling rate and bit resolution to produce resulting acquired video data for downstream processing. At operation 2, the discrete FPGA 150 communicates the acquired video data to the host 105 via the PCIe interface 160.

In the illustrated example, the integrated GPU 140 included in the host 105 processes the acquired video data communicated from the discrete FPGA 150 at operation 2 to make the acquired video data suitable for inferencing by one or more machine learning models. For example, the integrated GPU 140 may perform automatic white balancing (AWB), color space conversion (CSC), frame subsampling, etc., on the acquired video data. If the video cameras 120 and 125 implement one or more video encoding algorithms to encode the captured video signals into an encoded video format, the integrated GPU 140 may implement the counterpart video decoding algorithms to decode the acquired video data into decoded video data capable of being processed by the one or more machine learning models. At operation 3, the integrated GPU 140 communicates the processed/decoded video data to the secondary device 110 via the PCIe interface 155.

In the illustrated example, the discrete GPU 145 included in the secondary device 110 implements one or more machine learning models to perform inferencing on the processed/decoded video data provided by the host 105 at operation 3. For example, the discrete GPU 145 may implement machine learning model(s) to perform segmentation, object detection, object identification, etc., and/or any other inference operation on input video frames included in the processed/decoded video data provided by the host 105. In some examples, the machine learning model(s) implemented by the discrete GPU 145 output transparency information on a pixel basis that represents the inferencing results for each pixel of the input video frames. In such examples, the transparency information may be used to overlay information on the acquired video frames that identifies the inference results obtained by the machine learning models. For example, the transparency information may be used to overlay semi-transparent object identification information in different regions of the acquired video frames based on the inference results from the machine learning model(s). At operation 4, the discrete GPU 145 communicates the inference results, which may include the transparency information, to the host 105 via the PCIe interface 155.

In the illustrated example, the integrated GPU 140 obtains the inference results, which may include the transparency information, communicated from the discrete GPU 145 at operation 4. In the illustrated example, at operation 5, the CPU 135 and/or the GPU 140 read static information from the storage 130. For example, the storage 130 may store graphical data, such as logos, symbols, etc., and/or metadata, such as date and/or time information, location information, etc., to be used in the video analytics application. In some examples, the storage 130 may be implemented by any number and/or type(s) of memories, storage devices, etc., such as a nonvolatile memory express (NVME) solid state device (SSD) as shown in the example of FIG. 1.

In the illustrated example, the CPU 135 then invokes the integrated GPU 140 to merge the acquired video data, the inference results and the retrieved graphical data and/or metadata to determine an output of the video analytics application. For example, the output of the video analytics application may be video data that is annotated with the inference results provided by the machine learning model(s) implemented by the discrete GPU 145 and the graphical data and/or metadata obtained from the storage 130. At operation 6, the integrated GPU 140 store the output of the video analytics application to the storage

The example video analytics application described above illustrates the potential burdens placed on the system's PCIe interfaces 155 and 160 by the hybrid data processing architecture. For example, the bandwidth of the processed/decoded video data communicated by the integrated GPU 140 to the discrete GPU 145 via the PCIe interface 155 may be approximately 3 gigabytes (GB) per second (GB/s) corresponding to 4K video samples at 60 frames/second with 3 color channels and 10-bit resolution per channel. Additionally, the inference results communicated by the discrete GPU 145 to the integrated GPU 140 via the same PCIe interface 155 may be approximately 4 GB/s corresponding to 4K video samples at 60 frames/second with 3 color channels and 10-bit resolution per channel, plus an additional alpha channel conveying the per pixel transparency information including the inference results. Such a large overall data bandwidth can limit the number of video streams that can be processed in parallel by the video analytics application of the compute system 100. For example, the compute system 100 may implement an edge server that is expected to perform the above video analytics application for 96 video streams concurrently. In such an example, the required bandwidth over the PCIe interface 155 for the hybrid data processing architecture would be 288 GB/s for writing data from the host 105 to the secondary device 110, and 384 GB/s for reading from the secondary device 110 to the host 105, which exceeds the peak PCIe bandwidth of 256 GB/s.

The compute system 100 of the illustrated example implements interface data compression in accordance with teachings of this disclosure to reduce the PCIe bandwidth utilized for hybrid data processing. In the illustrated example, the host interface compression subsystem 165 of the host device 105 and the device interface compression subsystem 170 of the secondary device 110 implement interface data compression over the PCIe interface 155. Likewise, in the illustrated example, the host interface compression subsystem 165 of the host device 105 and the device interface compression subsystem 175 of the secondary device 115 implement interface data compression over the PCIe interface 160.

For example, to implement interface data compression over the PCIe interface 155, the host interface compression subsystem 165 of the host device 105 and the device interface compression subsystem 170 of the secondary device 110 perform an example initial compression negotiation procedure that occurs after system boot-up and/or during a platform pairing operation when the host device 105 discovers the secondary device 110 has been coupled to the system 100. In an example compression negotiation procedure, the host interface compression subsystem 165 of the host device 105 performs handshaking with the device interface compression subsystem 170 of the secondary device 110 to discover the interface compression capabilities, also referred to as bus interface compression capabilities, resident on the secondary device 110. For example, the bus interface compression capabilities may specify the type(s) and configuration(s) of the interface compression algorithm(s), also referred to as interface compression algorithm(s), that are resident on the secondary device 110 to compress data communicated over the PCIe interface 155. As used herein, an interface compression algorithm is resident on a device if the device is able to implement the interface compression algorithm to compress data communicated over a given bus interface without the need to download additional software and/or couple additional hardware to the device.

Next, based on the discovered interface compression capabilities of the secondary device 110, the host interface compression subsystem 165 of the host device 105 attempts to select a given interface compression algorithm that is both resident on the host device 105 and resident on the secondary device 110. If such a resident interface compression algorithm exists, the host interface compression subsystem 165 of the host device 105 then configures the selected interface compression algorithm for operation over the PCIe interface 155. For example, the host interface compression subsystem 165 of the host device 105 may communicate algorithm configuration parameters, such as a width of the compression boundary, one or more keys to be used to encrypt and/or decrypt data, etc., to the device interface compression subsystem 170 of the secondary device 110. The host interface compression subsystem 165 of the host device 105 and the device interface compression subsystem 170 of the secondary device 110 may then activate their respective interface compression algorithms to compress data communicated over the PCIe interface 155.

In some examples, if the host interface compression subsystem 165 of the host device 105 determines the secondary device 110 does not support an adequate resident interface compression capability, the host interface compression subsystem 165 may download compression software to the device interface compression subsystem 170 of the secondary device 110. The downloaded compression software can then be configured and executed by the device interface compression subsystem 170 of the secondary device 110 to provide data compression over the PCIe interface 155. In some examples, the host interface compression subsystem 165 may evaluate the interface compression capability information discovered for the secondary device 110 to determine whether the secondary device 110 has sufficient capabilities (e.g., compute, memory, etc.) to execute a software algorithm to compress data communicated over the PCIe interface 155. In such an example, if the secondary device 110 has sufficient capabilities, the host interface compression subsystem 165 downloads the compression software to the device interface compression subsystem 170 of the secondary device 110. In some examples, after download of the compression software is complete, the host interface compression subsystem 165 of the host device 105 configures the interface compression algorithm for operation over the PCIe interface 155, as described above.

In some examples, the host interface compression subsystem 165 of the host device 105 also dynamically adapts the compression used over the PCIe interface 155 during system runtime. In some such examples, the host interface compression subsystem 165 of the host device 105 may access compression context information associated with the data being communicated over the PCIe interface 155. For example, the host interface compression subsystem 165 of the host device 105 may access compression context information from one or more of the integrated GPU 140, the CPU 135 and/or the storage 130, etc. In some examples, the compression context information specifies, indicates, or otherwise describes one or more of the content of the data being communicated over the PCIe interface 155 (e.g., the type of video data, the type of inference results, etc.), one or more application associated with the data being communicated over the PCIe interface 155, statistics associated with the data being communicated over the PCIe interface 155 (e.g., such as machine learning model statistics provided by the discrete GPU 145), an amount of data being communicated over the PCIe interface 155 (e.g., the number of video streams for which video analytics is to be performed concurrently), etc.

Based on the accessed compression context information, the host interface compression subsystem 165 of the host device 105 may detect that a compression context change has occurred relative to an initial or expected compression context that was used to establish the interface compression over the PCIe interface 155 during the negotiation procedure described above. In some such examples, after detection of a compression context change, the host interface compression subsystem 165 of the host device 105 reconfigures the interface compression algorithm being used over the PCIe interface 155. For example, the host interface compression subsystem 165 of the host device 105 may communicate with the device interface compression subsystem 170 of the secondary device 110 to (i) adjust one or more parameters of the existing interface compression algorithm (e.g., such as a width of the compression boundary), or (ii) replace the existing compression algorithm with a different compression algorithm, etc. For example, the host interface compression subsystem 165 may determine that the context of the video data is more uniform than initially expected and increase the width of the compression boundary accordingly. In this way, the host interface compression subsystem 165 of the host device 105 can adapt the compression used over the PCIe interface 155 based on current system conditions (e.g., to increase the compression rate to support a higher effective data throughput, to decrease the compression rate to reduce power consumption while meeting performance targets, etc.).

Similarly, to implement interface data compression over the PCIe interface 160, the host interface compression subsystem 165 of the host device 105 and the device interface compression subsystem 175 of the secondary device 115 perform an example initial compression negotiation procedure that occurs after system boot-up and/or during a platform pairing operation when the host device 105 discovers the secondary device 115 has been coupled to the system 100. In an example compression negotiation procedure, the host interface compression subsystem 165 of the host device 105 performs handshaking with the device interface compression subsystem 175 of the secondary device 115 to discover the interface compression capabilities resident on the secondary device 115.

Next, based on the discovered interface compression capabilities of the secondary device 115, the host interface compression subsystem 165 of the host device 105 attempts to select a given interface compression algorithm that is both resident on the host device 105 and resident on the secondary device 115. If such a resident interface compression algorithm exists, the host interface compression subsystem 165 of the host device 105 then configures the selected interface compression algorithm for operation over the PCIe interface 160, as described above. However, if the host interface compression subsystem 165 of the host device 105 determines the secondary device 115 does not support an adequate resident interface compression capability, the host interface compression subsystem 165 may download compression software to the device interface compression subsystem 175 of the secondary device 115, as described above. The downloaded compression software can then be configured and executed by the device interface compression subsystem 175 of the secondary device 115 to provide data compression over the PCIe interface 160. In some examples, the interface compression algorithm selected or downloaded to implement data compression over the PCIe interface 160 may be the same as, or different from, the interface compression algorithm selected or downloaded to implement data compression over the PCIe interface 155.

In some examples, the host interface compression subsystem 165 of the host device 105 also dynamically adapts the compression used over the PCIe interface 160 during system runtime. In some such examples, the host interface compression subsystem 165 of the host device 105 may access compression context information associated with the data being communicated over the PCIe interface 160, as described above. Based on the accessed compression context information, the host interface compression subsystem 165 of the host device 105 may detect that a compression context change has occurred relative to an initial or expected compression context that was used to establish the interface compression over the PCIe interface 160 during the negotiation procedure described above. In some such examples, after detection of a compression context change, the host interface compression subsystem 165 of the host device 105 reconfigures the interface compression algorithm being used over the PCIe interface 160. For example, the host interface compression subsystem 165 of the host device 105 may communicate with the device interface compression subsystem 175 of the secondary device 115 to (i) adjust one or more parameters of the existing interface compression algorithm (e.g., such as a width of the compression boundary), or (ii) replace the existing compression algorithm with a different compression algorithm, etc. In this way, the host interface compression subsystem 165 of the host device 105 can also adapt the compression used over the PCIe interface 160 based on current system conditions (e.g., to increase the compression rate to support a higher effective data throughput, to decrease the compression rate to reduce power consumption while meeting performance targets, etc.).

In view of the foregoing, interface data compression as disclosed herein can reduce the data traffic across PCIe interfaces, enabling a true hybrid architecture by leveraging graphics, media and display assets across integrated and discrete devices. Interface data compression as disclosed herein can also overcome the hardware limitations. For example, the discrete GPU 145 may not support optical flow generation that is compatible with the video data provided by the FPGA 150. In such examples, the system 100 can use the integrated GPU 140 to perform such optical flow computations to compensate for the lack of such capability in the discrete GPU 145.

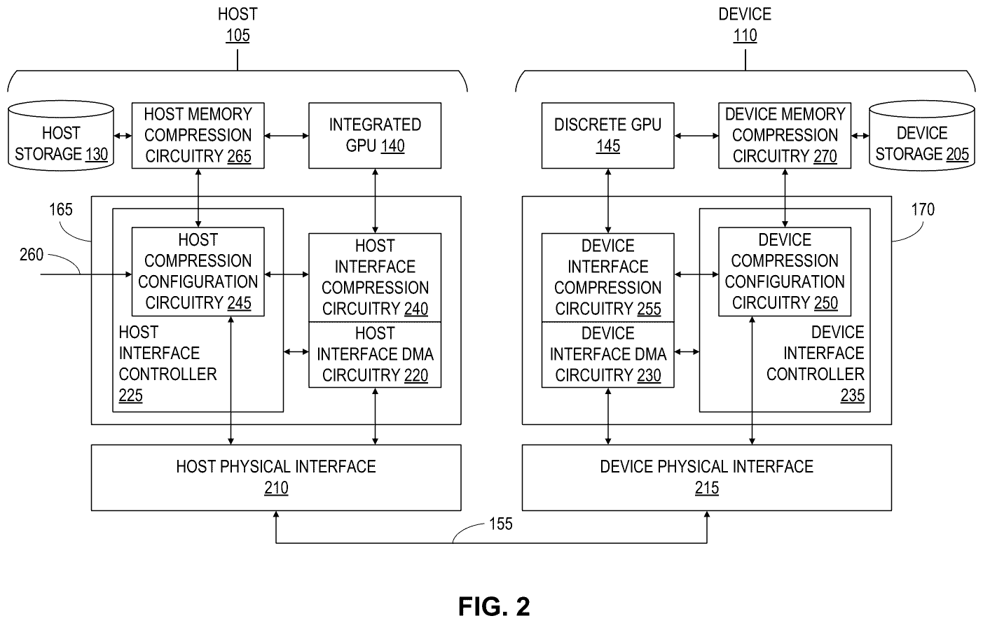

FIG. 2 is a block diagram of an example compute system 200 that corresponds to a portion of the example compute system 100 of FIG. 1. The compute system 200 of FIG. 2 includes an example implementation of the host device 105 and an example implementation of the secondary device 110 included in the compute system 100 of FIG. 1. In the illustrated example of FIG. 2, the host device 105 includes the storage 130, which is referred to as the host storage 130, and the integrated GPU 140 described above in connection with FIG. 1. In the illustrated example of FIG. 2, the secondary device 110 includes the discrete GPU 145 described above in connection with FIG. 1, as well as example device storage 205. In some examples, the device storage 205 may be implemented by any number and/or type(s) of memories, storage devices, etc.

In the illustrated example of FIG. 2, the host device 105 includes an example implementation of the host interface compression subsystem 165, and the secondary device 110 includes an example implementation of the device interface compression subsystem 170 described above in connection with FIG. 1. In the illustrated example, the host device 105 also includes an example host physical interface 210, and the secondary device 110 includes an example device physical interface 215. Together, the host interface compression subsystem 165, the host physical interface 210, the device interface compression subsystem 170 and the device physical interface 215 collectively implement the PCIe interface 155 described above in connection with FIG. 1 that couples the host device 105 and the secondary device 110. As such, the host physical interface 210 and the device physical interface 215 implement the appropriate pin connections and other circuitry to connect the host device 105 and the secondary device 110 via the PCIe interface 155.

The example host interface compression subsystem 165 and the example device interface compression subsystem 170 of FIG. 2 may be instantiated (e.g., creating an instance of, bring into being for any length of time, materialize, implement, etc.) by programmable circuitry, which may include one or more programmable circuits. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the example host interface compression subsystem 165 and the example device interface compression subsystem 170 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. It should be understood that some or all of the circuitry of FIG. 2 may, thus, be instantiated at the same or different times. Some or all of the circuitry of FIG. 2 may be instantiated, for example, in one or more threads executing concurrently on hardware and/or in series on hardware. Moreover, in some examples, some or all of the circuitry of FIG. 2 may be implemented by microprocessor circuitry executing instructions and/or FPGA circuitry performing operations to implement one or more virtual machines and/or containers.

Examining the example compute system 200 of FIG. 2 in further detail, the host interface compression subsystem 165 of the host device 105 includes example host interface direct memory access (DMA) circuitry 220 and an example host interface controller 225 to implement the data communication features on the host side of the PCIe interface 155. For example, the host interface controller 225 configures, in any appropriate manner, the host interface DMA circuitry 220 to perform DMA writes to send data over the PCIe interface 155 to the secondary device 110, and/or to perform DMA reads to receive data over the PCIe interface 155 from the secondary device 110. In the illustrated example, the host interface controller 225 configures, in any appropriate manner, the address space and other control aspects of the PCIe interface 155 between the host device 105 and the secondary device 110.

Similarly, the device interface compression subsystem 170 of the secondary device 110 includes example device interface DMA circuitry 230 and an example device interface controller 235 to implement the data communication features on the device side of the PCIe interface 155. For example, the device interface controller 235 configures, in any appropriate manner, the device interface DMA circuitry 230 to perform DMA writes to send data over the PCIe interface 155 to the host device 105, and/or to perform DMA reads to receive data over the PCIe interface 155 from the host device 105. In the illustrated example, the device interface controller 235 also configures, in any appropriate manner, the address space and other control aspects of the PCIe interface 155 between the host device 105 and the secondary device 110. For example, the host interface controller 225 may act as a primary interface controller and provide one or more commands to the device interface controller 235, which operates as a secondary interface controller responsive to the command(s) from the primary interface controller.

In the illustrated example of FIG. 2, the host interface compression subsystem 165 of the host device 105 also includes example host interface compression circuitry 240 and example host compression configuration circuitry 245 to implement data interface compression on the host side of the PCIe interface 155. In the illustrated example, the host interface controller 225 includes the host compression configuration circuitry 245 but, in some examples, the host compression configuration circuitry 245 may be separate from the host interface controller 225. The host interface compression circuitry 240 of the illustrated example implements one or more data compression algorithms such that they are resident on the host device 105. For example, the host interface compression circuitry 240 may implement the data compression algorithm(s) in hardware or a combination of hardware and software (e.g., such as in the form of machine-readable instructions executed by programmable circuitry) to compress data written (e.g., transmitted) from the host device 105 to the secondary device 110 via the PCIe interface 155, and/or decompress data read (e.g., received) by the host device 105 from the secondary device 110 via the PCIe interface 155. In some examples, the host interface compression circuitry 240 implements a data compression algorithm that has one or more configuration options that can be tailored to the type of data content being communicated over the PCIe interface 155. In some examples, the host interface compression circuitry 240 implements multiple data compression algorithms that are tailored to respective different types of data content that can be communicated over the PCIe interface 155.

For example, different types of data content that can be communicated over the PCIe interface 155 may include video content, measurement sensor content, text content, etc. As such, the host interface compression circuitry 240 may implement one or more resident data compression algorithms such that a first data compression algorithm may be selected if video content is to be communicated over the PCIe interface 155, a second data compression algorithm may be selected if measurement sensor content is to be communicated over the PCIe interface 155, a third data compression algorithm may be selected if text content is to be communicated over the PCIe interface 155, etc. In some examples, a given resident data compression algorithm implemented by the host interface compression circuitry 240 also includes one or more configuration parameters that can be varied based on the characteristics of the content being communicated over the PCIe interface 155. For example, a given resident data compression algorithm implemented by the host interface compression circuitry 240 may have a compression boundary width parameter that specifies the width of the compression boundary used by the data compression algorithm or, in other words, the block size used by the data compression algorithm to compress data. In such an example, the compression boundary width parameter may be increased for data that is relatively static or slowly changing, and reduced for data that is more variable, changing, etc.

In the illustrated example, the host compression configuration circuitry 245 is responsible for initiation and management of the interface data compression employed over the PCIe interface 155. For example, the host compression configuration circuitry 245 is responsible for performing the compression negotiation procedure described above and in further detail below to establish the data compression to be implemented over the PCIe interface 155. In some examples, the host compression configuration circuitry 245 is responsible for performing the runtime adaptation of the data compression implemented over the PCIe interface 155, as described above and in further detail below. Operation of the host compression configuration circuitry 245 is described in further detail below.

In some examples, the host interface compression subsystem 165 omits or bypasses the host interface compression circuitry 240. In some such examples, the integrated GPU 140 may implement one or more data compression algorithms to implement data compression over the PCIe interface 155. In such examples, the host compression configuration circuitry 245 may select and configure, or otherwise provide, the compression software to be executed by the integrated GPU 140 to implement the one or more data compression algorithms.

In the illustrated example of FIG. 2, the device interface compression subsystem 175 of the secondary device 110 also includes example device compression configuration circuitry 250 to implement data interface compression on the device side of the PCIe interface 155. In the illustrated example, the device interface controller 235 includes the device compression configuration circuitry 250 but, in some examples, the device compression configuration circuitry 250 may be separate from the device interface controller 235. In the illustrated example, the device compression configuration circuitry 250 cooperates with the host compression configuration circuitry 245 to initiate and manage the interface data compression employed over the PCIe interface 155. For example, the device compression configuration circuitry 250 is responsible for responding to commands from the host compression configuration circuitry 245 during the compression negotiation procedure described above and in further detail below to establish the data compression to be implemented over the PCIe interface 155. In some examples, the device compression configuration circuitry 250 is responsible for responding to commands from the host compression configuration circuitry 245 to perform runtime adaptation of the data compression implemented over the PCIe interface 155, as described above and in further detail below. Operation of the device compression configuration circuitry 250 is described in further detail below.

In some examples, the device interface compression subsystem 175 of the secondary device 110 optionally includes example device interface compression circuitry 255. If the device interface compression circuitry 255 is present, the device interface compression circuitry 255 implements one or more data compression algorithms such that they are resident on the secondary device 110. For example, the device interface compression circuitry 255 may implement the data compression algorithm(s) in hardware or a combination of hardware and software (e.g., such as in the form of machine-readable instructions executed by programmable circuitry) to compress data written (e.g., transmitted) from the secondary device 110 to the host device 105 via the PCIe interface 155, and/or decompress data read (e.g., received) by the secondary device 110 from the host device 105 via the PCIe interface 155. In some examples, the device interface compression circuitry 255 implements a data compression algorithm that has one or more configuration options that can be tailored to the type of data content being communicated over the PCIe interface 155, as described above. In some examples, the device interface compression circuitry 255 implements multiple data compression algorithms that are tailored to respective different types of data content that can be communicated over the PCIe interface 155, as described. However, one or more of the data compression algorithm(s) implemented by the device interface compression circuitry 255 may the same as, or different from, the data compression algorithm(s) implemented by the host interface compression circuitry 240 on the host side.

In some examples, the device interface compression subsystem 170 omits or bypasses the device interface compression circuitry 255. In some such examples, the discrete GPU 145 may implement one or more data compression algorithms to implement data compression over the PCIe interface 155. In such examples, the device compression configuration circuitry 250 may provide (e.g., upload) the compression software to be executed by the discrete GPU 145 to implement the one or more data compression algorithms.

Examining operation of the host compression configuration circuitry 245 and the device compression configuration circuitry 250 in further detail, to implement interface data compression over the PCIe interface 155, the host compression configuration circuitry 245 and the device compression configuration circuitry 250 begin by performing an example compression negotiation procedure, as described above. For example, the host compression configuration circuitry 245 initiates the compression negotiation procedure after boot-up of the system 200 and/or during a platform pairing operation when the host device 105 discovers the secondary device 110 has been coupled to the system 200. At the start of the compression negotiation procedure, host compression configuration circuitry 245 performs handshaking with the device compression configuration circuitry 250 to discover the interface compression capabilities resident on the secondary device 110. For example, if the device interface compression circuitry 255 is included in the device interface compression subsystem 175 of the secondary device 110, the interface compression capabilities returned by the device compression configuration circuitry 250 may specify the type(s) and configuration(s) of the interface compression algorithm(s) that are resident on the secondary device 110 to compress data communicated over the PCIe interface 155. Additionally or alternatively, the interface compression capabilities may specify the capabilities, such as compute capabilities, memory capabilities, etc., of the secondary device 110 (e.g., of the discrete GPU 145) to upload and execute compression software to implement one or more interface compression algorithm(s) to compress data communicated over the PCIe interface 155.

Next, based on the discovered interface compression capabilities of the secondary device 110, the host compression configuration circuitry 245 attempts to select a given interface compression algorithm that is both resident on the host device 105 and resident on the secondary device 110 (e.g., resident in the host interface compression circuitry 240 and resident in the device interface compression circuitry 255). In some examples, the host compression configuration circuitry 245 attempts to select the given interface compression algorithm based on the particular data content and/or characteristics of the data content to be communicated over the PCIe interface 155. In the illustrated example, the host compression configuration circuitry 245 includes an example compression context interface 260 to obtain information concerning one or more of the data content to be communicated over the PCIe interface 155, one or more characteristics of the data content, one or more characteristics of the system 200, etc. In some examples, the compression context interface 260 may be configured via an application programming interface (API) with the type of content to be communicated over the PCIe interface.

For example, the integrated GPU 140 may implement a video codec, the discrete GPU 145 may implement a machine learning algorithm, and the data to be communicated over the PCIe interface 155 may include decoded video data to be communicated from the host device 105 to the secondary device 110. In such an example, the compression context interface 260 may be configured via an API to specify that video data is to be communicated over the PCIe interface 155. In some examples, the host compression configuration circuitry 245 may use the interface compression capabilities returned by the device compression configuration circuitry 250 and the compression context information obtained via the compression context interface 260 to determine whether the host device 105 and the secondary device 110 each implement a resident interface data compression algorithm in common that is tailored to the data content to be communicated over the PCIe interface 155 (e.g., such as video data in the preceding example). If the host device 105 and the secondary device 110 (e.g., the host interface compression circuitry 240 and the device interface compression circuitry 255) implement such an interface data compression algorithm in common, the host compression configuration circuitry 245 selects that interface data compression algorithm to be used to implement data compression over the PCIe interface 155.

However, if such a resident interface data compression algorithm is not available at the secondary device 110, the host compression configuration circuitry 245 may evaluate the interface compression capabilities returned by the device compression configuration circuitry 250 to attempt to select another interface data compression algorithm that, although not tailored to the particular data content, is resident on both host device 105 and the secondary device 110. For example, the host compression configuration circuitry 245 may be configured (e.g., via the compression context interface 260) with a policy, one or more selection criteria, etc., to be used to perform interface data compression algorithm selection. If the host compression configuration circuitry 245 determines the host device 105 and the secondary device 110 (e.g., the host interface compression circuitry 240 and the device interface compression circuitry 255) implement one or more interface compression algorithms in common (e.g., that are compatible), the host compression configuration circuitry 245 selects, based on the policy, one or more criteria, etc., one of those interface compression algorithms in common to be used to implement data compression over the PCIe interface 155.

Assuming the host compression configuration circuitry 245 is able to select a resident interface compression algorithm that is resident on both the host device 105 and the secondary device 110 (e.g., the host interface compression circuitry 240 and the device interface compression circuitry 255), the host compression configuration circuitry 245 then configures the selected interface compression algorithm for operation over the PCIe interface 155. For example, the host compression configuration circuitry 245 may communicate information including configuration algorithm parameters, such as a width of the compression boundary, one or more keys to be used to encrypt and/or decrypt data, etc., to the device compression configuration circuitry 250. The host compression configuration circuitry 245 and the device compression configuration circuitry 250 may then instruct the host interface compression circuitry 240 and the device interface compression circuitry 255, respectively, to activate their respective, configured interface compression algorithms to compress data communicated over the PCIe interface 155.

In some examples, after evaluation of the interface compression capabilities returned by the device compression configuration circuitry 250, the host compression configuration circuitry 245 determines the secondary device 110 does not implement any resident interface data compression algorithms, or does not implement a resident interface data compression algorithm that is adequately compatible with a resident interface data compression algorithm of the host device 105. In some such examples, the host compression configuration circuitry 245 evaluates the interface compression capabilities returned by the device compression configuration circuitry 250 to determine whether the secondary device 110 has sufficient capabilities (e.g., compute, memory, etc.) to execute a software algorithm to compress data communicated over the PCIe interface 155. If so, in some examples, the host compression configuration circuitry 245 downloads compression software to the device compression configuration circuitry 250. In some examples, the device compression configuration circuitry 250 then configures the compression software for execution on the secondary device 110 (e.g., by the device interface compression circuitry 255, the discrete GPU 145, etc.) to provide data compression over the PCIe interface 155. For example, the compression software may provide one or more interface compression algorithms that are compatible with one or more of the interface compression algorithms implemented by the host interface compression circuitry 240. In some examples, after download of the compression software is complete, the host compression configuration circuitry 245 communicates information, such as one or more commands, to the device compression configuration circuitry 250 to permit configuration and activation of the interface compression algorithm to compress data over the PCIe interface 155, as described above.

In some examples, the host compression configuration circuitry 245 also dynamically adapts the compression used over the PCIe interface 155 during system runtime. In some such examples, the host compression configuration circuitry 245 may access, via the compression context interface 260, compression context information that specifies characteristic(s) associated with the data being communicated over the PCIe interface 155. For example, the compression context interface 260 may be configured via an API with compression context information obtained from one or more of the integrated GPU 140, the discrete GPU 145, the storage 130. In some examples, the compression context information specifies, indicates, or otherwise describes one or more of the content of the data being communicated over the PCIe interface 155 (e.g., the type of video data, the type of inference results, etc.), one or more application associated with the data being communicated over the PCIe interface 155 statistics (e.g., such as machine learning model statistics provided by the discrete GPU 145), an amount of data being communicated over the PCIe interface 155 (e.g., the number of video streams for which video analytics is to be performed concurrently), etc.

Based on the accessed compression context information, the host compression configuration circuitry 245 may detect that a compression context change has occurred relative to an initial or expected compression context that was used to establish the interface compression over the PCIe interface 155 during the negotiation procedure described above. In some such examples, after detection of a compression context change, the host compression configuration circuitry 245 may communicate with device compression configuration circuitry 250 to negotiate (i) adjustment of one or more parameters of the existing interface compression algorithm (e.g., such as a width of the compression boundary), (ii) replacement of the existing compression algorithm with a different compression algorithm, etc. After a negotiation success, the host compression configuration circuitry 245 communicates information to the device compression configuration circuitry 250 to reconfigure the interface compression algorithm being used over the PCIe interface 155 based on the negotiation results. For example, the host compression configuration circuitry 245 may determine that the context of the video data is more uniform than initially expected and increase the width of the compression boundary accordingly. In this way, the host compression configuration circuitry 245 can adapt the compression used over the PCIe interface 155 based on current system conditions (e.g., to increase the compression rate to support a higher effective data throughput, to decrease the compression rate to reduce power consumption while meeting performance targets, etc.).

In some examples, the host device 105 also includes example host memory compression circuitry 265 to implement one or more data compression algorithms to implement data compression between the integrated GPU 140 and the storage 130. For example, the host memory compression circuitry 265 may compress data written by the integrated GPU 140 to the storage 130, and decompress data read by the integrated GPU 140 from the storage 130. In some examples, the host compression configuration circuitry 245 controls operation of the host memory compression circuitry 265 (e.g., based on information obtained via the compression context interface 260). In some examples, the host compression configuration circuitry 245 causes the host interface compression circuitry 240 and the host memory compression circuitry 265 to implement data compression concurrently such that compression is active on both the PCIe interface 155 and the interface between the integrated GPU 140 and the storage 130. However, in some examples, the host compression configuration circuitry 245 causes the host interface compression circuitry 240 to activate data compression on the PCIe interface 155 while the host memory compression circuitry 265 is inactive and does not implement data compression between the integrated GPU 140 and the storage 130. However, in some examples, the host compression configuration circuitry 245 causes the host interface compression circuitry 240 to be inactive such that data compression is not implemented on the PCIe interface 155 while the host memory compression circuitry 265 is active and implements data compression between the integrated GPU 140 and the storage 130.

Similarly, in some examples, the secondary device 110 also includes example device memory compression circuitry 270 to implement one or more data compression algorithms to implement data compression between the discrete GPU 145 and the storage 205. For example, the device memory compression circuitry 270 may compress data written by the discrete GPU 145 to the storage 205, and decompress data read by the discrete GPU 145 from the storage 205. In some examples, the device compression configuration circuitry 250 controls operation of the device memory compression circuitry 270. In some examples, the device compression configuration circuitry 250 causes the device interface compression circuitry 255 and the device memory compression circuitry 270 to implement data compression concurrently such that compression is active on both the PCIe interface 155 and the interface between the discrete GPU 145 and the storage 205. However, in some examples, the device compression configuration circuitry 250 causes the device interface compression circuitry 255 to activate data compression on the PCIe interface 155 while the device memory compression circuitry 270 is inactive and does not implement data compression between the discrete GPU 145 and the storage 205. However, in some examples, the device compression configuration circuitry 250 causes the device interface compression circuitry 255 to be inactive such that data compression is not implemented on the PCIe interface 155 while the device memory compression circuitry 270 is active and implements data compression between the discrete GPU 145 and the storage 205.

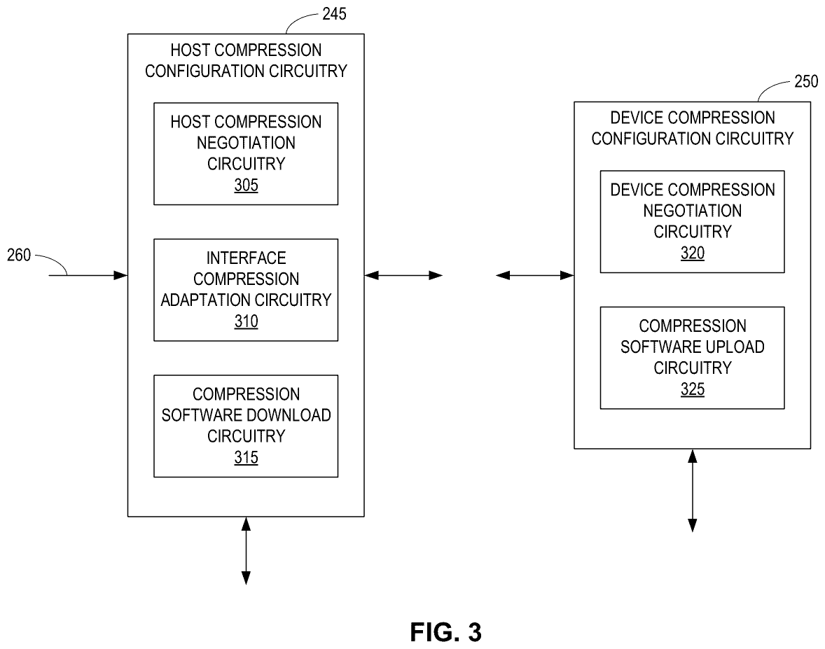

FIG. 3 illustrates an example implementation of the host compression configuration circuitry 245 included in the host interface compression subsystem 165 of FIG. 2. FIG. 3 also illustrates an example implementation of the device compression configuration circuitry 250 included in the device interface compression subsystem 170 of FIG. 2. Turning to FIG. 3, the host compression configuration circuitry 245 of the illustrated example includes example host compression negotiation circuitry 305, example interface compression adaptation circuitry 310 and example compression software download circuitry 315. The host compression negotiation circuitry 305 of the illustrated example implements the host-side portion of the example interface compression negotiation procedure described herein. The interface compression adaptation circuitry 310 of the illustrated example implements the run-time adaptation of the interface compression algorithm operating over the PCIe interface, as described herein. The software download circuitry 315 of the illustrated example implements the compression software download procedure, as described herein.

The example device compression configuration circuitry 250 of FIG. 3 includes example device compression negotiation circuitry 320 and example compression software upload circuitry 325. The device compression negotiation circuitry 320 of the illustrated example implements the device-side portion of the example interface compression negotiation procedure described herein. The software upload circuitry 325 of the illustrated example implements the compression software upload procedure for the secondary device 110, as described herein.

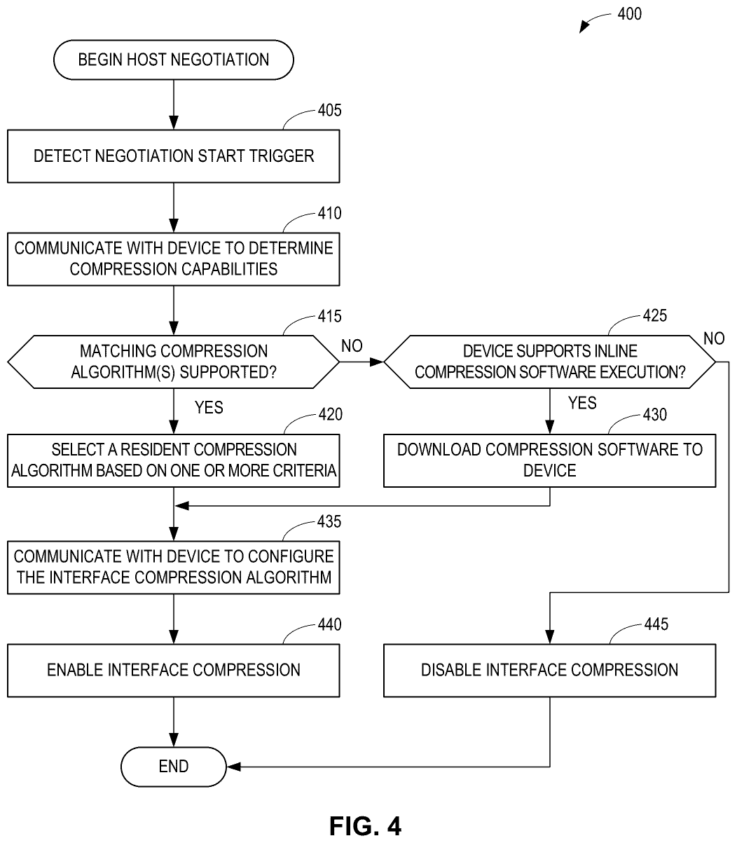

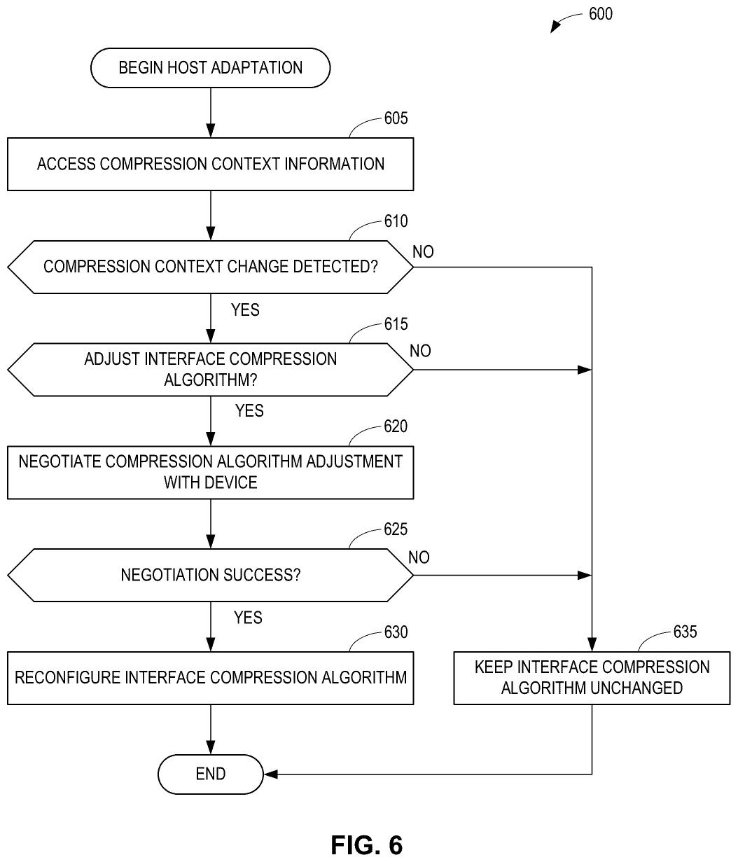

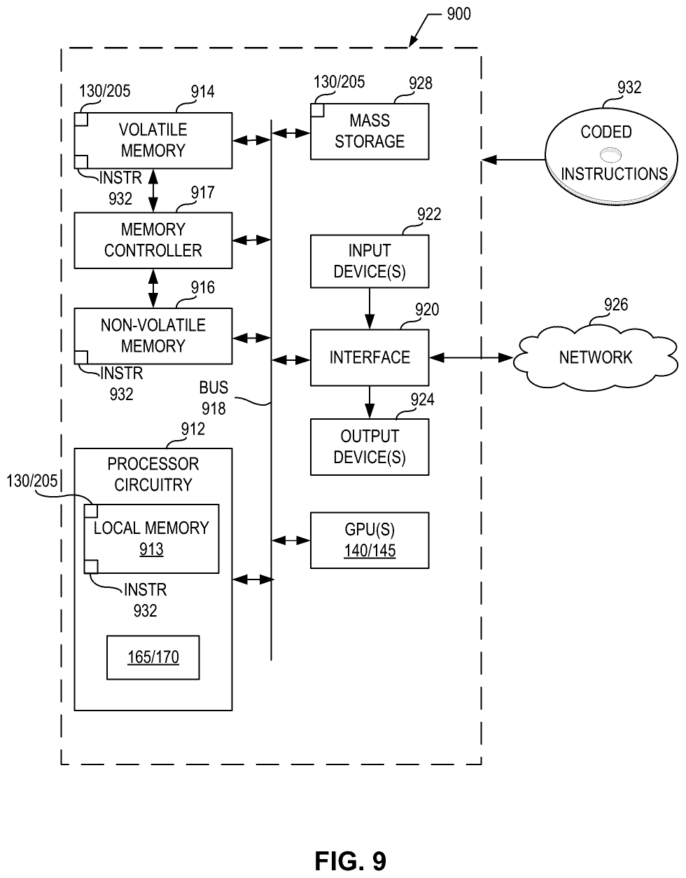

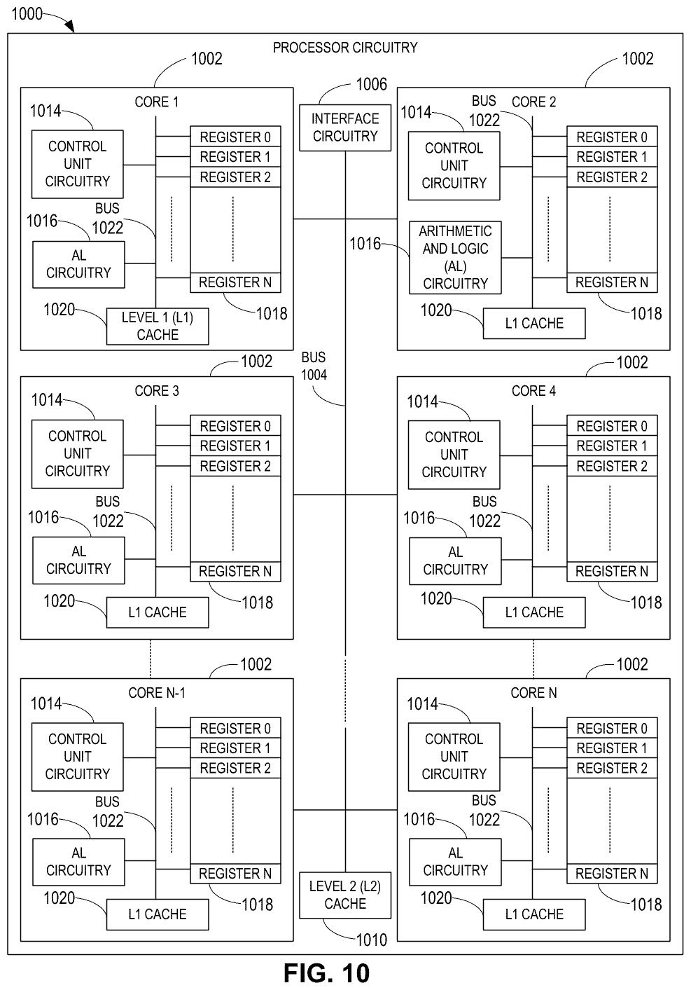

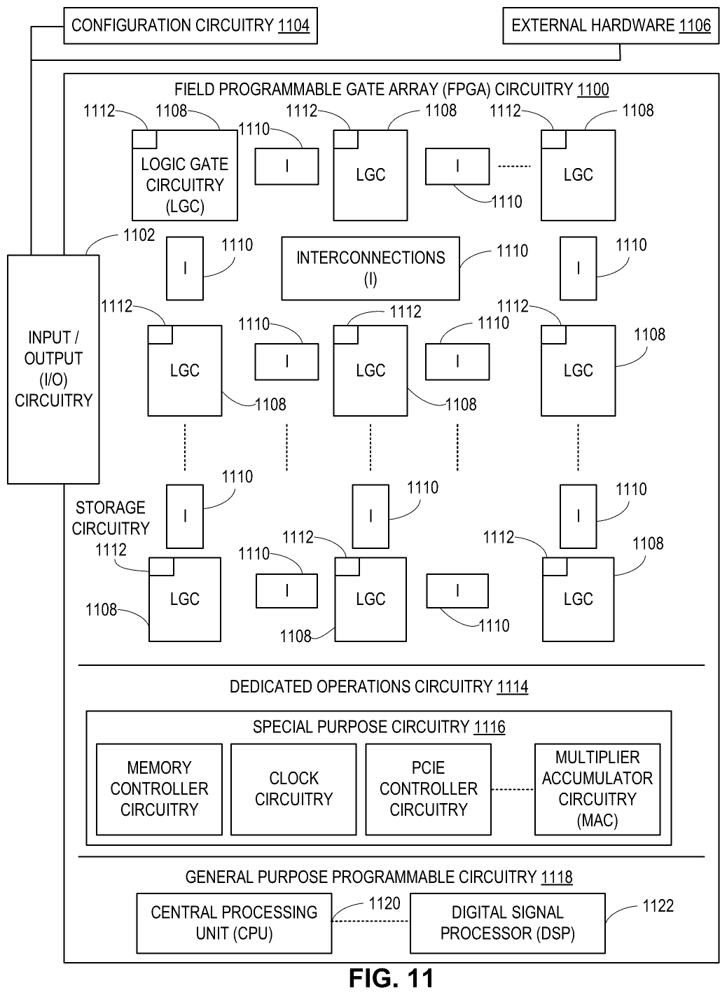

In some examples, the host interface compression subsystem 165 includes means configuring compression at a host for a data interface between the host and a device. For example, the means for configuring compression at the host may be implemented by the host compression configuration circuitry 245. In some examples, the host compression configuration circuitry 245 may be instantiated by programmable circuitry such as the example programmable circuitry 912 of FIG. 9. For instance, the host compression configuration circuitry 245 may be instantiated by the example microprocessor 1000 of FIG. 10 executing machine executable instructions such as those implemented by at least blocks 405-445 of FIG. 4 and/or blocks 605-635 of FIG. 6. In some examples, the host compression configuration circuitry 245 may be instantiated by hardware logic circuitry, which may be implemented by an ASIC, XPU, or the FPGA circuitry 1100 of FIG. 11 configured and/or structured to perform operations corresponding to the machine-readable instructions. Additionally or alternatively, the host compression configuration circuitry 245 may be instantiated by any other combination of hardware, software, and/or firmware. For example, the host compression configuration circuitry 245 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

In some examples, the host interface compression subsystem 165 includes means performing data compression at a host for a data interface between the host and a device. For example, the means for performing data compression at the host may be implemented by the host interface compression circuitry 240. In some examples, the host interface compression circuitry 240 may be instantiated by programmable circuitry such as the example programmable circuitry 912 of FIG. 9. For instance, the host interface compression circuitry 240 may be instantiated by the example microprocessor 1000 of FIG. 10 executing machine executable instructions such as those implemented by at least block 440 of FIG. 4. In some examples, the host interface compression circuitry 240 may be instantiated by hardware logic circuitry, which may be implemented by an ASIC, XPU, or the FPGA circuitry 1100 of FIG. 11 configured and/or structured to perform operations corresponding to the machine-readable instructions. Additionally or alternatively, the host interface compression circuitry 240 may be instantiated by any other combination of hardware, software, and/or firmware. For example, the host interface compression circuitry 240 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise

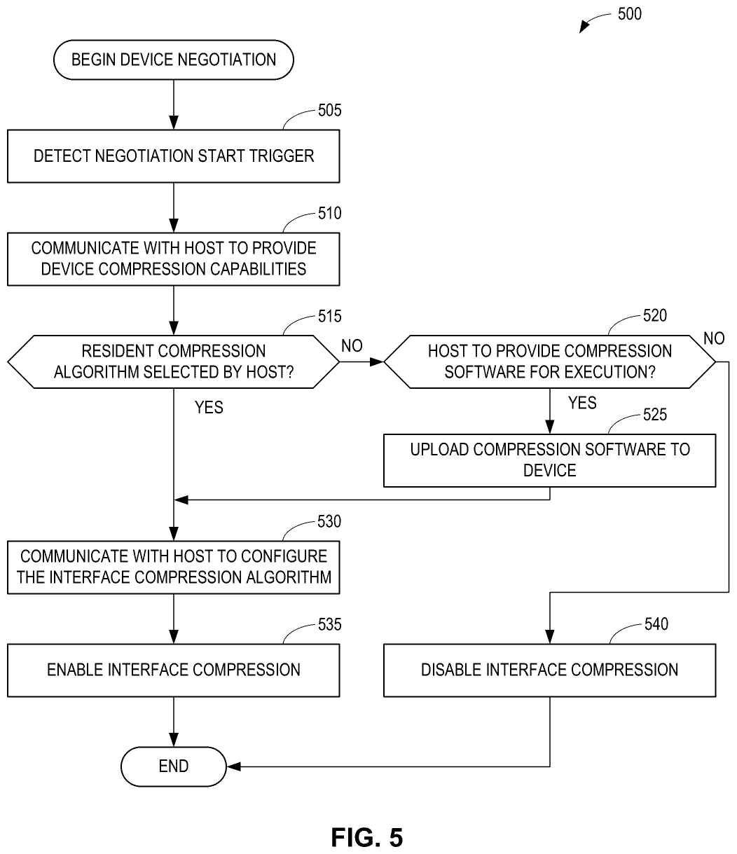

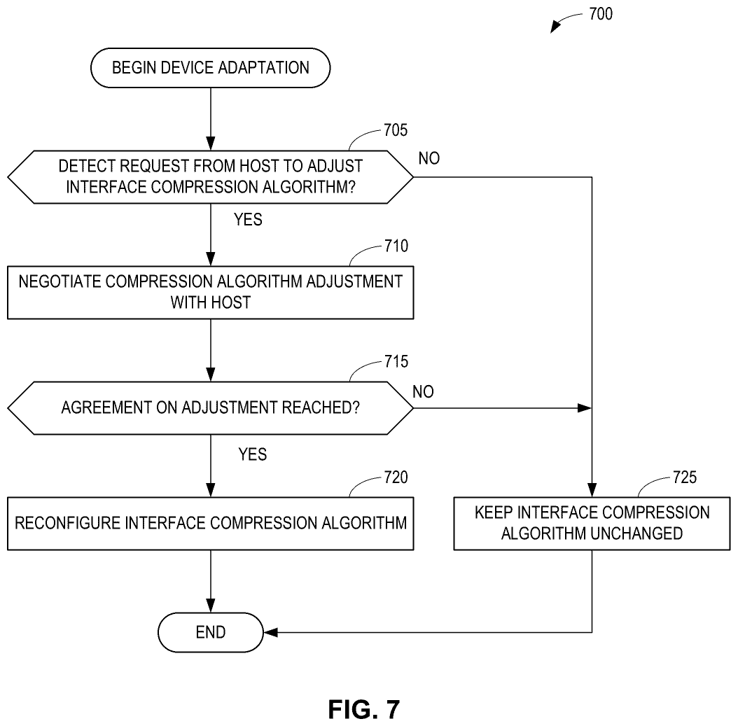

In some examples, the device interface compression subsystem 170 includes means configuring compression at a device for a data interface between the device and a host. For example, the means for configuring compression at the device may be implemented by the device compression configuration circuitry 250. In some examples, the device compression configuration circuitry 250 may be instantiated by programmable circuitry such as the example programmable circuitry 912 of FIG. 9. For instance, the device compression configuration circuitry 250 may be instantiated by the example microprocessor 1000 of FIG. 10 executing machine executable instructions such as those implemented by at least blocks 505-540 of FIG. 5 and/or blocks 705-725 of FIG. 7. In some examples, the device compression configuration circuitry 250 may be instantiated by hardware logic circuitry, which may be implemented by an ASIC, XPU, or the FPGA circuitry 1100 of FIG. 11 configured and/or structured to perform operations corresponding to the machine-readable instructions. Additionally or alternatively, the device compression configuration circuitry 250 may be instantiated by any other combination of hardware, software, and/or firmware. For example, the device compression configuration circuitry 250 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine-readable instructions and/or to perform some or all of the operations corresponding to the machine-readable instructions without executing software or firmware, but other structures are likewise appropriate.

While an example manner of implementing the host interface compression subsystem 165 and the device interface compression subsystem 170 of FIG. 1 is illustrated in FIGS. 2-3, one or more of the elements, processes, and/or devices illustrated in FIGS. 2-3 may be combined, divided, re-arranged, omitted, eliminated, and/or implemented in any other way. Further, the example host interface compression circuitry 240, the example host compression configuration circuitry 245, the example device compression configuration circuitry 250, the example device interface compression circuitry 255, the example host compression negotiation circuitry 305, the example interface compression adaptation circuitry 310, the example compression software download circuitry 315, the example device compression negotiation circuitry 320, the example compression software upload circuitry 325 and/or, more generally, the example host interface compression subsystem 165 and the example device interface compression subsystem 170 of FIGS. 2-3, may be implemented by hardware alone or by hardware in combination with software and/or firmware. Thus, for example, any of the example host interface compression circuitry 240, the example host compression configuration circuitry 245, the example device compression configuration circuitry 250, the example device interface compression circuitry 255, the example host compression negotiation circuitry 305, the example interface compression adaptation circuitry 310, the example compression software download circuitry 315, the example device compression negotiation circuitry 320, the example compression software upload circuitry 325 and/or, more generally, the example host interface compression subsystem 165 and the example device interface compression subsystem 170, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine-readable instructions (e.g., firmware or software). Further still, the example host interface compression circuitry 240, the example host compression configuration circuitry 245, the example device compression configuration circuitry 250, the example device interface compression circuitry 255, the example host compression negotiation circuitry 305, the example interface compression adaptation circuitry 310, the example compression software download circuitry 315, the example device compression negotiation circuitry 320, the example compression software upload circuitry 325 and/or, more generally, the example host interface compression subsystem 165 and the example device interface compression subsystem 170 of FIG. 1 may include one or more elements, processes, and/or devices in addition to, or instead of, those illustrated in FIGS. 2-3, and/or may include more than one of any or all of the illustrated elements, processes and devices.

Flowchart(s) representative of example machine-readable instructions, which may be executed by programmable circuitry to implement and/or instantiate the example host interface compression subsystem 165 and the example device interface compression subsystem 170 of FIGS. 2-3 and/or representative of example operations which may be performed by programmable circuitry to implement and/or instantiate the example host interface compression subsystem 165 and the example device interface compression subsystem 170 of FIGS. 2-3, are shown in FIGS. 4-7. The machine-readable instructions may be one or more executable programs or portion(s) of one or more executable programs for execution by programmable circuitry such as the programmable circuitry 912 shown in the example processor platform 900 discussed below in connection with FIG. 9 and/or may be one or more function(s) or portion(s) of functions to be performed by the example programmable circuitry (e.g., an FPGA) discussed below in connection with FIGS. 10 and/or 11. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer-readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer-readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIGS. 4-7, many other methods of implementing the example host interface compression subsystem 165 and the device interface compression subsystem 170 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer-readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 4-7 may be implemented using executable instructions (e.g., computer-readable and/or machine-readable instructions) stored on one or more non-transitory computer-readable and/or machine-readable media. As used herein, the terms non-transitory computer-readable medium, non-transitory computer-readable storage medium, non-transitory machine-readable medium, and/or non-transitory machine-readable storage medium are expressly defined to include any type of computer-readable storage device and/or storage disk and to exclude propagating signals and to exclude transmission media. Examples of such non-transitory computer-readable medium, non-transitory computer-readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer-readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer-readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer-readable instructions, machine-readable instructions, etc., and/or manufactured to execute computer-readable instructions, machine-readable instructions, etc.

FIG. 4 is a flowchart representative of example machine-readable instructions and/or example operations 400 that may be executed, instantiated, and/or performed by programmable circuitry to implement host-side interface compression negotiation in the host interface compression subsystem 165 of FIGS. 2-3. The example machine-readable instructions and/or the example operations 400 of FIG. 4 begin at block 405 at which the host interface compression subsystem 165 of the host device 105 detects a negotiation start trigger, such as a host boot-up even, a device discovery event, etc., as described above. At block 410, the host interface compression subsystem 165 communicates with secondary device 110 to determine interface compression capabilities of the secondary device 110, as described above. At block 415, the host interface compression subsystem 165 determines, as described above and based on the discovered interface compression capabilities, whether matching (e.g., compatible) interface data compression algorithms are resident on the host device 105 and resident on the secondary device.

If matching (e.g., compatible) interface data compression algorithms are resident on the host device 105 and resident on the secondary device (corresponding to the “YES” output of block 415), then at block 420 the host interface compression subsystem 165 selects a resident interface data compression algorithm based on one or more criteria, as described above. However, if matching (e.g., compatible) interface data compression algorithms are not resident on the host device 105 and resident on the secondary device (corresponding to the “NO” output of block 415), at block 425 the host interface compression subsystem 165 determines, as described above, whether the secondary device 110 has sufficient capabilities (e.g., compute, memory, etc.) to support inline compression software execution. If the secondary device 110 has sufficient capabilities (corresponding to the “YES” output of block 425), then at block 430 the host interface compression subsystem 165 download compression software to the secondary device 110, as described above.

Next, at block 435, the host interface compression subsystem 165 communicates information to the secondary device 435 to configure the interface compression algorithm (e.g., resident or software) to be used to compress data over the PCIe interface between the host device 105 and the secondary device 110. At block 440, the host interface compression subsystem 165 communicates a command or other interface to cause interface compression to be enabled on the PCIe interface between the host device 105 and the secondary device 110. However, if the secondary device 110 does not have sufficient capabilities to support software inline compression (corresponding to the “NO” output of block 425), then at block 445 the host interface compression subsystem 165 causes interface compression to be disabled on the PCIe interface between the host device 105 and the secondary device 110, as described above. The example machine-readable instructions and/or the example operations 400 then end.

FIG. 5 is a flowchart representative of example machine-readable instructions and/or example operations 500 that may be executed, instantiated, and/or performed by programmable circuitry to implement device-side interface compression negotiation in the device interface compression subsystem 170 of FIGS. 2-3. The example machine-readable instructions and/or the example operations 500 of FIG. 5 begin at block 505 at which the device interface compression subsystem 170 of the secondary device 110 detects an interface compression negotiation start trigger, such as a communication from the host device 105, as described above. At block 510, the device interface compression subsystem 170 communicates with the host device 105 to provide interface compression capabilities of the secondary device 110, as described above. Next, the device interface compression subsystem 170 determines, based on information from the host device 105 obtained after the interface compression capability information is provided the host device 105, whether the host device 105 is to activate an interface compression algorithm resident on the secondary device 110 or provide compression software to the secondary device 110, as described above.

For example, at block 515, the device interface compression subsystem 170 determines whether information from the host device 105 indicates that a resident interface compression algorithm on the secondary device 110 has been selected by the host device 105 to be used to implement data compression on the PCIe interface 155. If a resident interface compression algorithm has not been selected (corresponding to the “NO” output of block 515), then at block 520 the device interface compression subsystem 170 determine whether information from the host device 105 indicates compression software will be provided for execution. If compression software is to be provided (corresponding to the “YES” output of block 520), then at block 825 the device interface compression subsystem 170 uploads compression software form the host device 105 to the secondary device 110, as described above.

If the information from the host device 105 indicates a resident interface compression algorithm has been selected (corresponding to the “YES” output of block 515), or after the compression software is uploaded at block 525, then at block 530 the device interface compression subsystem 170 communicates with the host device 105 to received information to configure the interface compression algorithm for operation on the PCIe interface 155, as described above. At block 535, the device interface compression subsystem 170 then activates data compression on the PCIe interface 155. However, a resident interface compression algorithm is not selected by the host device 105 (corresponding to the “NO” output of block 515), and compression software is not to be provided by the host device 105 (corresponding to the “NO” output of block 520), at block 540 the device interface compression subsystem 170 disables data compression on the PCIe interface 155. The example machine-readable instructions and/or the example operations 500 then end.

FIG. 6 is a flowchart representative of example machine-readable instructions and/or example operations 600 that may be executed, instantiated, and/or performed by programmable circuitry to implement host-side interface compression adaptation in the host interface compression subsystem 165 of FIGS. 2-3. The example machine-readable instructions and/or the example operations 600 of FIG. 6 begin at block 605 at which the host interface compression subsystem 165 of the host device 105 accesses compression context information, as described above. At block 610, the host interface compression subsystem 165 evaluates the compression context information to determine whether a compression context has changed relative to the context associated with the current data compression algorithm being used on the PCIe interface 155, as described above. If a compression context change is detected (corresponding to the “YES” output of block 610), at block 615 the host interface compression subsystem 165 determines whether the context change warrants a change in the current data compression algorithm being used on the PCIe interface 155. If a change is warranted (corresponding to the “YES” output of block 615), at block 620 the host interface compression subsystem 165 communicates with the secondary device to negotiate an adjustment to data compression algorithm used on the PCIe interface 155, as described above.

At block 625, the host interface compression subsystem 165 determines whether the negotiation is successful. If the negotiation is successful (corresponding to the “YES” output of block 625), the host interface compression subsystem 165 reconfigures the data compression algorithm to be used on the PCIe interface 155, as described above. However, if a compression context change is not detected (corresponding to the “NO” output of block 610), a change is not warranted (corresponding to the “NO” output of block 615), or negotiation is unsuccessful (corresponding to the “NO” output of block 625), the host interface compression subsystem 165 keeps the data compression algorithm being used on the PCIe interface 155 unchanged. The example machine-readable instructions and/or the example operations 600 then end.

FIG. 7 is a flowchart representative of example machine-readable instructions and/or example operations 700 that may be executed, instantiated, and/or performed by programmable circuitry to implement device-side interface compression adaptation in the device interface compression subsystem 170 of FIGS. 2-3. The example machine-readable instructions and/or the example operations 700 of FIG. 7 begin at block 705 at which device interface compression subsystem 170 of the secondary device 110 operates to detect a request from the host device 105 to adjust the data compression algorithm being used for the PCIe interface 155. If a request is detected (corresponding to the “YES” output of block 705), at block 710 the device interface compression subsystem 170 negotiates, as described above, a compression algorithm adjustment with the host device 105. At block 715, the device interface compression subsystem 170 determines whether negotiation was successful and an agreement on the compression algorithm adjustment was reached.

If negotiation was successful (corresponding to the “YES” output of block 715), then at block 720 the device interface compression subsystem 170 reconfigures the data compression algorithm to be used on the PCIe interface 155, as described above. However, if a request to adjust the interface compression algorithm is not detected (corresponding to the “NO” output of block 705), or negotiation was unsuccessful (corresponding to the “NO” output of block 715), at block 725 the device interface compression subsystem 170 keeps the data compression algorithm being used on the PCIe interface 155 unchanged. The example machine-readable instructions and/or the example operations 700 then end.

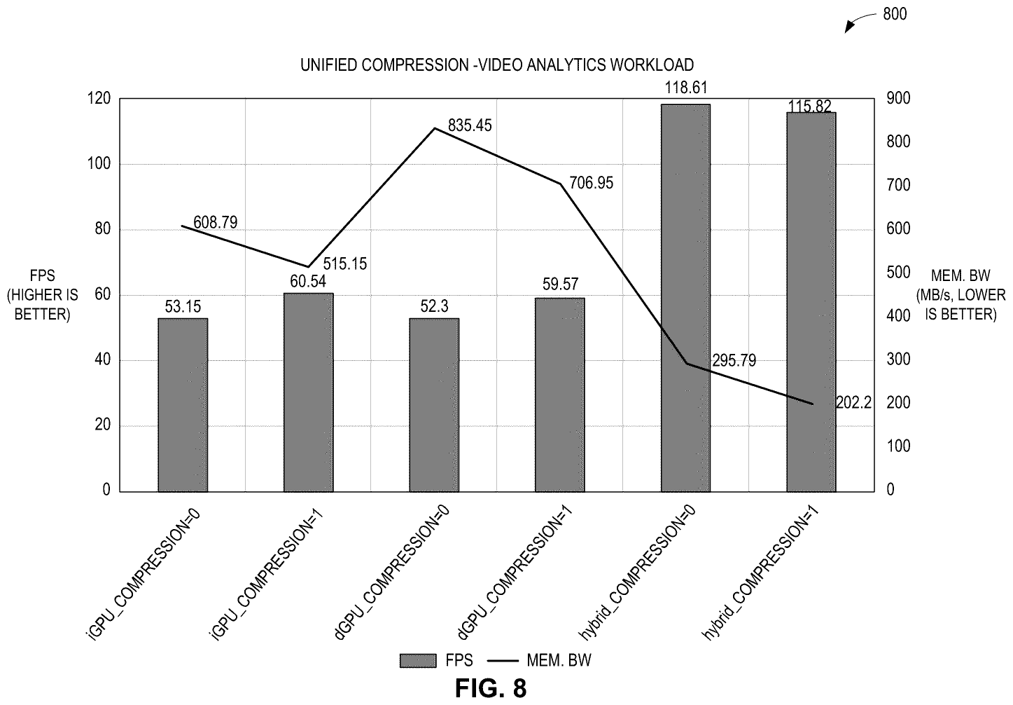

FIG. 8 example performance results 800 achievable by interface data compression techniques for hybrid data processing as disclosed herein. The performance results 800 correspond to an example workload implemented by the compute system 200 in which incoming video streams are decoded, downscaled and processed by multiple levels of machine learning models. For example, an object detection machine learning model detects objects in a video frame. The inference outputs of the object detection machine learning model are fed to multiple object classification machine learning models to compute the age, gender and mood of the detected objects.

The performance results 800 of the illustrated example depict example frames-per-second throughput and example memory bandwidth consumption achieved by example implementations of the workload the include (i) an example implementation 805 on the host device 105 alone without memory compression, (ii) an example implementation 810 on the host device 105 alone with memory compression, (iii) an example implementation 815 on the secondary device 110 alone without memory compression, (iv) an example implementation 820 on the discrete device 110 alone with memory compression, (v) an example hybrid implementation 825 based on an example hybrid architecture as described above without interface compression on the PCIe interface, and (vi) an example hybrid implementation 830 based on an example hybrid architecture as described above with interface compression on the PCIe interface. As can be seen from FIG. 8, the frames-per-second throughput for the hybrid implementations 825 and 830 are similar and substantially better than the standalone implementations 805-820 (e.g., by a factor of at least 2). Moreover, the hybrid implementation 830 is able to reduce memory bandwidth consumption by a factor of ˜33% relative to the hybrid implementation 825 without data compression over the PCIe interface.

FIG. 9 is a block diagram of an example programmable circuitry platform 900 structured to execute and/or instantiate the example machine-readable instructions and/or the example operations of FIGS. 4-7 to implement the example host interface compression subsystem 165 and/or the example device interface compression subsystem 170 of FIGS. 2-3. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 900 of the illustrated example includes programmable circuitry 912. The programmable circuitry 912 of the illustrated example is hardware. For example, the programmable circuitry 912, which may include one or more programmable circuits, can be implemented by one or more integrated circuits, logic circuits, FPGAs, microprocessors, CPUs, GPUs, VPUs, DSPs, and/or microcontrollers from any desired family or manufacturer. The programmable circuitry 912 may be implemented by one or more semiconductor based (e.g., silicon based) devices. In some examples, the programmable circuitry 912 corresponds to the host device 105 and implements the host interface compression subsystem 165. In some examples, the programmable circuitry 912 corresponds to the secondary device 110 and implements the device interface compression subsystem 170.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by flash memory and/or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916. In some examples, the memory 914 and/or 916 corresponds to the host device 105 and implements the host storage 130. In some examples, the memory 914 and/or 916 corresponds to the secondary device 110 and implements the device storage 205.

The programmable circuitry platform 900 of the illustrated example also includes interface circuitry 920. The interface circuitry 920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter data and/or commands into the programmable circuitry 912. The input device(s) 922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 924 are also connected to the interface circuitry 920 of the illustrated example. The output device(s) 924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 920 of the illustrated example, thus, typically includes a graphics driver card, a graphics driver chip, and/or graphics processor circuitry such as a GPU.

The interface circuitry 920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store firmware, software, and/or data. Examples of such mass storage discs or devices 928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs. In some examples, the storage discs or devices 928 correspond to the host device 105 and implement the host storage 130. In some examples, the storage discs or devices 928 correspond to the secondary device 110 and implement the device storage 205.

The machine-readable instructions 932, which may be implemented by the machine-readable instructions of FIGS. 4-7, may be stored in the mass storage device 928, in the volatile memory 914, in the non-volatile memory 916, and/or on at least one non-transitory computer-readable storage medium such as a CD or DVD which may be removable.

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIGS. 4-7 to effectively instantiate the circuitry of FIGS. 2-3 as logic circuits to perform operations corresponding to those machine-readable instructions. In some such examples, the circuitry of FIGS. 2-3 is instantiated by the hardware circuits of the microprocessor 1000 in combination with the machine-readable instructions. For example, the microprocessor 1000 may be implemented by multi-core hardware circuitry such as a CPU, a DSP, a GPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine-readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine-readable instructions and/or operations represented by the flowcharts of FIGS. 4-7.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Additionally or alternatively, the first bus 1004 may be implemented by any other type of computing or electrical bus. The cores 1002 may obtain data, instructions, and/or signals from one or more external devices by example interface circuitry 1006. The cores 1002 may output data, instructions, and/or signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and/or instructions. Data and/or instructions may be transferred (e.g., shared) by writing to and/or reading from the shared memory 1010. The local memory 1020 of each of the cores 1002 and the shared memory 1010 may be part of a hierarchy of storage devices including multiple levels of cache memory and the main memory (e.g., the main memory 914, 916 of FIG. 9). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic and/or logic operations on the data within the corresponding core 1002. The AL circuitry 1016 of some examples performs integer-based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and/or instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 and/or, more generally, the microprocessor 1000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1000 is a semiconductor device fabricated to include many transistors interconnected to implement the structures described above in one or more integrated circuits (ICs) contained in one or more packages.

The microprocessor 1000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1000, in the same chip package as the microprocessor 1000 and/or in one or more separate packages from the microprocessor 1000.

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine-readable instructions. However, once configured, the FPGA circuitry 1100 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine-readable instructions represented by the flowchart(s) of FIGS. 4-7 but whose interconnections and logic circuitry are fixed once fabricated), the FPGA circuitry 1100 of the example of FIG. 11 includes interconnections and logic circuitry that may be configured, structured, programmed, and/or interconnected in different ways after fabrication to instantiate, for example, some or all of the operations/functions corresponding to the machine-readable instructions represented by the flowchart(s) of FIGS. 4-7. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 4-7. As such, the FPGA circuitry 1100 may be configured and/or structured to effectively instantiate some or all of the operations/functions corresponding to the machine-readable instructions of the flowchart(s) of FIGS. 4-7 as dedicated logic circuits to perform the operations/functions corresponding to those software instructions in a dedicated manner analogous to an ASIC. Therefore, the FPGA circuitry 1100 may perform the operations/functions corresponding to the some or all of the machine-readable instructions of FIGS. 4-7 faster than the general-purpose microprocessor can execute the same.

In the example of FIG. 11, the FPGA circuitry 1100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

The FPGA circuitry 1100 of FIG. 11, includes example input/output (I/O) circuitry 1102 to obtain and/or output data to/from example configuration circuitry 1104 and/or external hardware 1106. For example, the configuration circuitry 1104 may be implemented by interface circuitry that may obtain a binary file, which may be implemented by a bit stream, data, and/or machine-readable instructions, to configure the FPGA circuitry 1100, or portion(s) thereof. In some such examples, the configuration circuitry 1104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine-readable instructions of FIGS. 4-7 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of the electrical structures and/or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 and/or an example DSP 1122. Other general purpose programmable circuitry 1118 may additionally or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may additionally be implemented by combining at least the example microprocessor 1000 of FIG. 10 and the example FPGA circuitry 1100 of FIG. 11. In some such hybrid examples, one or more cores 1002 of FIG. 10 may execute a first portion of the machine-readable instructions represented by the flowchart(s) of FIGS. 4-7 to perform first operation(s)/function(s), the FPGA circuitry 1100 of FIG. 11 may be configured and/or structured to perform second operation(s)/function(s) corresponding to a second portion of the machine-readable instructions represented by the flowcharts of FIG. 4-7, and/or an ASIC may be configured and/or structured to perform third operation(s)/function(s) corresponding to a third portion of the machine-readable instructions represented by the flowcharts of FIGS. 4-7.

It should be understood that some or all of the circuitry of FIGS. 2-3 may, thus, be instantiated at the same or different times. For example, same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be configured and/or structured to perform operations/functions corresponding to portion(s) of machine-readable instructions at the same and/or different times.

In some examples, some or all of the circuitry of FIGS. 2-3 may be instantiated, for example, in one or more threads executing concurrently and/or in series. For example, the microprocessor 1000 of FIG. 10 may execute machine-readable instructions in one or more threads executing concurrently and/or in series. In some examples, the FPGA circuitry 1100 of FIG. 11 may be configured and/or structured to carry out operations/functions concurrently and/or in series. Moreover, in some examples, some or all of the circuitry of FIGS. 2-3 may be implemented within one or more virtual machines and/or containers executing on the microprocessor 1000 of FIG. 10.

In some examples, the programmable circuitry 912 of FIG. 9 may be in one or more packages. For example, the microprocessor 1000 of FIG. 10 and/or the FPGA circuitry 1100 of FIG. 11 may be in one or more packages. In some examples, an XPU may be implemented by the programmable circuitry 912 of FIG. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

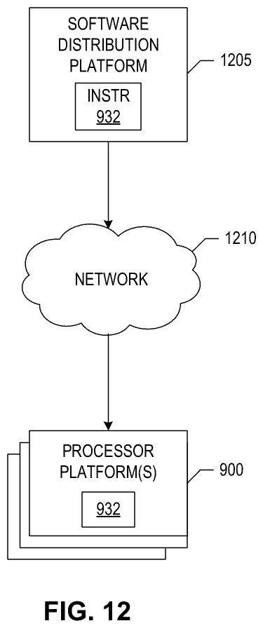

A block diagram illustrating an example software distribution platform 1205 to distribute software such as the example machine-readable instructions 932 of FIG. 9 to other hardware devices (e.g., hardware devices owned and/or operated by third parties from the owner and/or operator of the software distribution platform) is illustrated in FIG. 12. The example software distribution platform 1205 may be implemented by any computer server, data facility, cloud service, etc., capable of storing and transmitting software to other computing devices. The third parties may be customers of the entity owning and/or operating the software distribution platform 1205. For example, the entity that owns and/or operates the software distribution platform 1205 may be a developer, a seller, and/or a licensor of software such as the example machine-readable instructions 932 of FIG. 9. The third parties may be consumers, users, retailers, OEMs, etc., who purchase and/or license the software for use and/or re-sale and/or sub-licensing. In the illustrated example, the software distribution platform 1205 includes one or more servers and one or more storage devices. The storage devices store the machine-readable instructions 932, which may correspond to the example machine-readable instructions of FIGS. 4-7, as described above. The one or more servers of the example software distribution platform 1205 are in communication with an example network 1210, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third-party payment entity. The servers enable purchasers and/or licensors to download the machine-readable instructions 932 from the software distribution platform 1205. For example, the software, which may correspond to the example machine-readable instructions of FIG. 4-7, may be downloaded to the example programmable circuitry platform 900, which is to execute the machine-readable instructions 932 to implement the host interface compression subsystem 165 and the device interface compression subsystem 170. In some examples, one or more servers of the software distribution platform 1205 periodically offer, transmit, and/or force updates to the software (e.g., the example machine-readable instructions 932 of FIG. 9) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that implement interface data compression for hybrid data processing architectures such that data compression is provided at the system interface, such as a PCIe interface, between a host device and a secondary device of the system. Disclosed systems, apparatus, articles of manufacture, and methods improve the efficiency of using a computing device by reducing the PCIe interface bandwidth utilized to communicate data between the host device and the secondary device(s) to implement hybrid data processing applications, thereby freeing up bandwidth for other applications and/or allowing the hybrid data processing applications to process more workloads. Disclosed systems, apparatus, articles of manufacture, and methods are accordingly directed to one or more improvement(s) in the operation of a machine such as a computer or other electronic and/or mechanical device.

Further examples and combinations thereof include the following. Example 1 includes an apparatus comprising interface circuitry, machine-readable instructions, and at least one programmable circuit to be programmed based on the machine-readable instructions to communicate with a device to determine interface compression capability information, determine, based on the interface compression capability information, whether a host and the device implement one or more interface compression algorithms in common, the one or more interface compression algorithms to provide data compression over a bus interface between a host and the device, and configure, in response to a determination that the host and the device implement one or more interface compression algorithms in common, a first interface compression algorithm of the one or more interface compression algorithms to operate on the host and on the device to compress data communicated over the bus interface.

Example 2 includes any preceding clause(s) of example 1, wherein the bus interface is a peripheral component interconnect express (PCIe) interface implemented by the interface circuitry.

Example 3 includes any preceding clause(s) of examples 1-2, wherein one or more of the at least one programmable circuit is included in a PCIe controller associated with the PCIe interface.

Example 4 includes any preceding clause(s) of examples 1-3, wherein one or more of the at least one programmable circuit is to initiate communication with the device to obtain the interface compression capability information based on at least one of discovery of the device or boot-up of the host.

Example 5 includes any preceding clause(s) of examples 1-4, wherein one or more of the at least one programmable circuit is to select the first interface compression algorithm based on a characteristic of the data to be communicated over the bus interface between the host and the device.

Example 6 includes any preceding clause(s) of examples 1-5, wherein the apparatus includes a first graphics processing unit (GPU), the device includes a second GPU, the first GPU is to implement a video codec, the second GPU is to implement a machine learning algorithm, and the data to be communicated over the bus interface between the host and the device includes decoded video data to be communicated from the host to the device.

Example 7 includes any preceding clause(s) of examples 1-6, wherein one or more of the at least one programmable circuit is to, in response to a determination that the host and the device do not implement one or more interface compression algorithms in common cause a download of compression software to the device, the device to execute the compression software to implement a second interface compression algorithm in common with the host, and configure the second interface compression algorithm to operate on the host and on the device.

Example 8 includes any preceding clause(s) of examples 1-7, wherein one or more of the at least one programmable circuit is to communicate with the device to negotiate an adjustment to be made to the first interface compression algorithm configured to operate on the host and on the device, and reconfigure a parameter of the first interface compression algorithm on the host and on the device in response to detection of a negotiation success.

Example 9 includes any preceding clause(s) of examples 1-8, wherein one or more of the at least one programmable circuit is to communicate with the device to negotiate a compression adjustment; and configure a second interface compression algorithm of the one or more interface compression algorithms to operate on the host and on the device in response to detection of a negotiation success, the second interface compression algorithm different from the first interface compression algorithm.

Example 10 includes an apparatus comprising interface circuitry, machine-readable instructions, and at least one programmable circuit to be programmed based on the machine-readable instructions to provide interface compression capability information to a host, determine, based on configuration information from the host obtained in response to the interface compression capability information provided to the host, whether the host is to at least one of activate a first interface compression algorithm implemented by a device or provide compression software to the device, the first interface compression algorithm to provide data compression over a bus interface between the host and the device, the compression software to implement a second interface compression algorithm to provide data compression over the bus interface between the host and the device, and based on the configuration information, at least one of configure the first interface compression algorithm to operate on the device, or configure the compression software to execute on the device.

Example 11 includes any preceding clause(s) of example 10, wherein the bus interface is a peripheral component interconnect express (PCIe) interface implemented by the interface circuitry.

Example 12 includes any preceding clause(s) of examples 10-11, wherein one or more of the at least one programmable circuit is included in a PCIe controller associated with the PCIe interface.

Example 13 includes any preceding clause(s) of examples 10-12, including a graphics processing unit (GPU) to execute the compression software.

Example 14 includes any preceding clause(s) of examples 10-13, wherein the GPU is to implement a machine learning model, the machine learning model to process decoded video data obtained from the host via the bus interface.

Example 15 includes any preceding clause(s) of examples 10-14, wherein the apparatus includes a first graphics processing unit (GPU), the device includes a second GPU, the first GPU is to implement a video codec, the second GPU is to implement a machine learning model, and data to be communicated over the bus interface between the host and the device includes decoded video data to be communicated from the host to the device.

Example 16 includes any preceding clause(s) of examples 10-15, wherein the configuration information from the host is first configuration information, and one or more of the at least one programmable circuit is to configure the first interface compression algorithm to operate on the device based on the first configuration information, communicate with the host to negotiate an adjustment to be made to the first interface compression algorithm, and reconfigure a parameter of the first interface compression algorithm based on second configuration information from the host.

Example 17 includes any preceding clause(s) of examples 10-16, wherein the configuration information from the host is first configuration information, and one or more of the at least one programmable circuit is to configure the first interface compression algorithm to operate on the device based on the first configuration information, communicate with the host to negotiate a compression adjustment, and replace, based on second configuration information from the host, the first interface compression algorithm with a different interface compression algorithm implemented by the device.

Example 18 includes at least one non-transitory machine-readable medium comprising instructions to cause at least one programmable circuit of a host to at least determine, based on interface compression capability information from a device, whether the host and the device implement one or more interface compression algorithms in common, the one or more interface compression algorithms to provide data compression over a bus interface between the host and the device, and configure, in response to a determination that the host and the device implement one or more interface compression algorithms in common, a first interface compression algorithm of the one or more interface compression algorithms to operate on the host and on the device to compress data communicated over the bus interface.

Example 19 includes any preceding clause(s) of example 18, wherein the bus interface is a peripheral component interconnect express (PCIe) interface, and the one or more of the at least one programmable circuit is included in a PCIe controller of the host.

Example 20 includes any preceding clause(s) of examples 18-19, wherein the instructions are to cause one or more of the at least one programmable circuit to, in response to a determination that the host and the device do not implement one or more interface compression algorithms in common cause a download of compression software to the device, the device to execute the compression software to implement a second interface compression algorithm in common with the host, and configure the second interface compression algorithm to operate on the host and on the device.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
interface circuitry;
machine-readable instructions; and
at least one programmable circuit to be programmed based on the machine-readable instructions to:
communicate with a device to determine interface compression capability information;
determine, based on the interface compression capability information, whether a host and the device implement one or more interface compression algorithms in common, the one or more interface compression algorithms to provide data compression over a bus interface between a host and the device; and
configure, in response to a determination that the host and the device implement one or more interface compression algorithms in common, a first interface compression algorithm of the one or more interface compression algorithms to operate on the host and on the device to compress data communicated over the bus interface.

2. The apparatus of claim 1, wherein the bus interface is a peripheral component interconnect express (PCIe) interface implemented by the interface circuitry.

3. The apparatus of claim 2, wherein one or more of the at least one programmable circuit is included in a PCIe controller associated with the PCIe interface.

4. The apparatus of claim 1, wherein one or more of the at least one programmable circuit is to initiate communication with the device to obtain the interface compression capability information based on at least one of discovery of the device or boot-up of the host.

5. The apparatus of claim 1, wherein one or more of the at least one programmable circuit is to select the first interface compression algorithm based on a characteristic of the data to be communicated over the bus interface between the host and the device.

6. The apparatus of claim 5, wherein the apparatus includes a first graphics processing unit (GPU), the device includes a second GPU, the first GPU is to implement a video codec, the second GPU is to implement a machine learning algorithm, and the data to be communicated over the bus interface between the host and the device includes decoded video data to be communicated from the host to the device.

7. The apparatus of claim 1, wherein one or more of the at least one programmable circuit is to, in response to a determination that the host and the device do not implement one or more interface compression algorithms in common:
cause a download of compression software to the device, the device to execute the compression software to implement a second interface compression algorithm in common with the host; and
configure the second interface compression algorithm to operate on the host and on the device.

8. The apparatus of claim 1, wherein one or more of the at least one programmable circuit is to:
communicate with the device to negotiate an adjustment to be made to the first interface compression algorithm configured to operate on the host and on the device; and
reconfigure a parameter of the first interface compression algorithm on the host and on the device in response to detection of a negotiation success.

9. The apparatus of claim 1, wherein one or more of the at least one programmable circuit is to at least one of:
communicate with the device to negotiate a compression adjustment; and
configure a second interface compression algorithm of the one or more interface compression algorithms to operate on the host and on the device in response to detection of a negotiation success, the second interface compression algorithm different from the first interface compression algorithm.

10. An apparatus comprising:
interface circuitry;
machine-readable instructions; and
at least one programmable circuit to be programmed based on the machine-readable instructions to:
provide interface compression capability information to a host;
determine, based on configuration information from the host obtained in response to the interface compression capability information provided to the host, whether the host is to at least one of activate a first interface compression algorithm implemented by a device or provide compression software to the device, the first interface compression algorithm to provide data compression over a bus interface between the host and the device, the compression software to implement a second interface compression algorithm to provide data compression over the bus interface between the host and the device; and
based on the configuration information, at least one of configure the first interface compression algorithm to operate on the device, or configure the compression software to execute on the device.

11. The apparatus of claim 10, wherein the bus interface is a peripheral component interconnect express (PCIe) interface implemented by the interface circuitry.

12. The apparatus of claim 11, wherein one or more of the at least one programmable circuit is included in a PCIe controller associated with the PCIe interface.

13. The apparatus of claim 10, including a graphics processing unit (GPU) to execute the compression software.

14. The apparatus of claim 13, wherein the GPU is to implement a machine learning model, the machine learning model to process decoded video data obtained from the host via the bus interface.

15. The apparatus of claim 10, wherein the apparatus includes a first graphics processing unit (GPU), the device includes a second GPU, the first GPU is to implement a video codec, the second GPU is to implement a machine learning model, and data to be communicated over the bus interface between the host and the device includes decoded video data to be communicated from the host to the device.

16. The apparatus of claim 10, wherein the configuration information from the host is first configuration information, and one or more of the at least one programmable circuit is to:
configure the first interface compression algorithm to operate on the device based on the first configuration information;
communicate with the host to negotiate an adjustment to be made to the first interface compression algorithm; and
reconfigure a parameter of the first interface compression algorithm based on second configuration information from the host.

17. The apparatus of claim 10, wherein the configuration information from the host is first configuration information, and one or more of the at least one programmable circuit is to:
configure the first interface compression algorithm to operate on the device based on the first configuration information;
communicate with the host to negotiate a compression adjustment; and
replace, based on second configuration information from the host, the first interface compression algorithm with a different interface compression algorithm implemented by the device.

18. At least one non-transitory machine-readable medium comprising instructions to cause at least one programmable circuit of a host to at least:
determine, based on interface compression capability information from a device, whether the host and the device implement one or more interface compression algorithms in common, the one or more interface compression algorithms to provide data compression over a bus interface between the host and the device; and
configure, in response to a determination that the host and the device implement one or more interface compression algorithms in common, a first interface compression algorithm of the one or more interface compression algorithms to operate on the host and on the device to compress data communicated over the bus interface.

19. The at least one non-transitory machine-readable medium of claim 18, wherein the bus interface is a peripheral component interconnect express (PCIe) interface, and the one or more of the at least one programmable circuit is included in a PCIe controller of the host.

20. The at least one non-transitory machine-readable medium of claim 19, wherein the instructions are to cause one or more of the at least one programmable circuit to, in response to a determination that the host and the device do not implement one or more interface compression algorithms in common:
cause a download of compression software to the device, the device to execute the compression software to implement a second interface compression algorithm in common with the host; and
configure the second interface compression algorithm to operate on the host and on the device.
